(19) United States
(12) Patent Application Publication
(10) Pub. No.: US 2009/0191327 A1
(43) Pub. Date: Jul. 30, 2009

(54) VACUUM COATING INSTALLATION AND METHOD OF PRODUCING A COATING LAYER ON A SUBSTRATE

(75) Inventors: Hans-Georg Lotz, Gruendau-Rothenbergen (DE); Peter Sauer, Schluechtern (DE)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 12/276,533

(22) Filed: Nov. 24, 2008

Related U.S. Application Data
(60) Provisional application No. 61/023,691, filed on Jan. 25, 2008.

(30) Foreign Application Priority Data
Jan. 25, 2008 (EP) 08100933.4 - 1215

(51) Int. Cl. C23C 14/54

(52) U.S. Cl. 427/10; 427/9; 118/723 VE

(57) ABSTRACT

A strip coating system includes a first pulley carrying a flexible metal or Al substrate wound up on the first pulley. A second, take-up, pulley is provided for taking up the coated substrate. The coating process is a continuous coating process, during which the first pulley and the second pulley are rotated to move the substrate continuously past a coating tool for depositing coating particles on a surface of the substrate. After having passed the coating section with a speed v, the substrate carrying a coating layer on the surface thereof passes an infrared spectroscopic measurement device for measuring the layer thickness of the coating layer. Feedback controls are provided to control one or more process parameters of the coating tool responsive to the measurement of the thickness of the coating layer detected by the measurement tool. Thus, an in situ online measurement of the thickness of the coating layer may be implemented.

### CROSS-REFERENCES TO RELATED APPLICATIONS

This application is a nonprovisional of, and claims the benefit of the filing date of, U.S. Provisional Patent Application No. 61/023,691, entitled “Vacuum Coating Installation and Method of Producing a Coating Layer on a Substrate,” filed Jan. 25, 2008 by Hans-Georg Lotz and Peter Sauer, the entire disclosure of which is incorporated herein by reference for all purposes.

This application also claims priority to EP 08100933.4-1215, filed Jan. 25, 2008 by Hans-Georg Lotz and Peter Sauer, the entire disclosure of which is incorporated herein by reference for all purposes.

### BACKGROUND OF THE INVENTION

This application relates to a vacuum coating installation. More specifically, this application relates to a vacuum coating installation comprising a coating chamber, coating tools for depositing a coating layer on a substrate in a coating section of said coating chamber, and a mechanism for determining a physical characteristic, particularly a thickness, of the coating layer deposited on the substrate. In addition, the application relates to a method of producing a coating layer on a substrate, comprising the steps of: a) providing a continuously moving substrate in a coating chamber; b) depositing a coating layer having a physical characteristic, particularly a thickness, on a first section of the surface of the substrate in the coating chamber while the first section of the surface of the substrate passes the coating section; and c) determining the physical characteristic, particularly the thickness, of the coating layer deposited on the first section of the surface of the substrate downstream the coating section in the coating chamber by using an infrared (IR) spectroscopic measuring method. Moreover, the application relates to a method of measuring the thickness of a silicon layer deposited on a substrate.

In many technical applications, thin layers or stacks of thin layers are required. It is apparent that after deposition of a layer or a stack of layers, particular physical characteristics of the layer(s) have to be measured in order to ensure an acceptable and consistent quality of the layer system. One parameter to be measured is the thickness of a layer deposited on a substrate. Because the thickness of a layer affects a number of physical properties of the layer system, the measurement of the thickness of the layer can be particularly important.

The selection of a suitable measurement and detection system for determining a layer thickness depends on the material of the coating layer and the properties of the substrate, as well as on the arrangement of layers in the layer system. In fact, a number of measurement and detection methods are known. For example, the thickness of a layer may be determined by measuring reflection and/or transmission effects, e.g. the interference of a first wave reflected from the surface of a layer deposited on a substrate and a second wave reflected from the surface of the substrate. Such methods include single-wavelength measurements and spectral-wavelength-range measurements, e.g. in a visible and ultraviolet (UV) range.

However, for determining the thickness of a layer of particular material, the methods usually employed are not suitable. For example, the measurement of the thickness of a silicon layer produced in a vacuum coating installation is difficult. Furthermore, for determining the thickness of silicon layers used in solar applications, the results of optical measurements are often deteriorated because the surfaces of such layers may be structured or patterned. The structured or patterned surfaces cause scattering of light and spurious interference effects. Another problem is the relatively high absorption of light in silicon layers.

Furthermore, a number of measurement methods may only be carried out after the deposition of a layer and after removal of the substrate from a coating chamber in a separate process. Therefore, it may not be possible to react immediately when the thickness of the layer diverges from a nominal range.

### BRIEF SUMMARY OF THE INVENTION

It is an object of the present invention to provide a vacuum coating installation and a method of producing a coating layer on a substrate, allowing a reliable measurement of a layer characteristic, particularly the thickness of the layer, in the production process of the layer, even if the surface of the layer is structured or patterned. Another object is that the system and the method allow a fast reaction in the coating process when the thickness of the layer diverges from a nominal range.

### BRIEF DESCRIPTION OF THE DRAWINGS

Features and advantages of the present invention will be apparent from the following description and the attached drawings.

FIG. 1 is a schematic view of a vacuum strip coating system according to an embodiment of the invention; and

FIG. 2 is a schematic view of a thickness-determining mechanism according to an embodiment of the invention.

### DETAILED DESCRIPTION OF THE INVENTION

Embodiments of the invention provide a vacuum coating installation and a method of producing a coating layer on a substrate.

A vacuum coating installation according to embodiments of the invention may comprise a coating chamber; coating tools for depositing a coating layer on a substrate in a coating section of the coating chamber; and a mechanism for determining a physical characteristic, particularly a thickness, of the coating layer deposited on the substrate. The mechanism for determining the physical characteristic may comprise an infrared spectroscopic measuring device arranged downstream of the coating section for measuring the physical characteristic, particularly the thickness, of the coating layer deposited on the substrate. The vacuum coating installation includes a feedback control unit for controlling one or more parameters of the vacuum coating installation responsive to the physical characteristic determined by the determining mechanism for controlling the thickness of a coating layer deposited in the coating section. The determining mechanism is comprised by the vacuum coating installation.

Whereas in conventional systems, the thickness of a layer is determined in a separate process, i.e. ex situ, embodiments of the present invention provide the determining mechanism as part of the coating installation, thus providing the possibility of an in situ measurement of the thickness of a layer.

Embodiments of the invention refer especially to the measurement of the thickness of a silicon layer deposited on a metal substrate or a substrate e.g. a plastic substrate, coated with a metal layer in a strip coating installation. Silicon layers are required in many technical applications, such as in solar-cell applications, and may have a patterned or structured surface. However, generally other properties may be determined, e.g. properties of layer stacks or of silicon layers being deposited on top of intermediate layers arranged between the silicon layer and the substrate.

The coating tools are coating tools for depositing e.g. a silicon coating layer or a silicon layer on a substrate. As used herein, the term “silicon coating layer” may comprise any layer that includes at least a fraction of silicon. The coating process is carried out in a vacuum atmosphere. Any suitable coating process, e.g. an evaporation coating process, a CVD coating process, a PVD coating process, a sputter coating process, a plasma-supported coating process, etc., may be used.

For implementing the in situ measurement of the thickness of the silicon layer, a suitable measuring device may be provided that allows the measurement of the physical property, particularly the thickness of the layer, in a vacuum atmosphere. Determining a physical characteristic includes determining a physical property (e.g. the thickness) or an alteration of the physical property. Besides, the measuring device may allow a reliable measurement of the characteristic even if a pattern or structure is formed on the surface of the layer. Furthermore, a fast measuring method is provided that allows a fast reaction when the determined characteristic deviates from a nominal value or nominal range of values. The parameters of the coating process may be controlled to compensate for the deviation.

The control unit may comprise a feedback control using the thickness of the coating layer as a control parameter in order to control the process parameters influencing the thickness of the coating layer during the coating process. Therefore, the layer properties may advantageously be monitored in situ and online during the manufacturing process using one or a plurality of sensors arranged at suitable positions in the coating installation. A change in the amplitude or the shape of the reflected peak may indicate a change of a characteristic, and particularly of the thickness, of the silicon layer.

Particularly, the determining mechanism may comprise a measurement mechanism for measuring the physical characteristic, particularly the thickness, of the coating layer deposited on the substrate.

The thickness of a coating layer may be measured in the vacuum coating chamber in a vacuum atmosphere substantially immediately after the coating layer has been deposited on a first substrate or a first section of an elongated substrate. At the same time, the coating process may continue for depositing a coating layer on a second substrate or on a second section of the elongated substrate. When using the systems and methods of the invention, particularly in a strip coating device, including an in situ measurement, modifications of the characteristics (e.g. the thickness of a silicon layer deposited on a substrate) may already be determined in the vacuum coating chamber, thereby allowing a prompt reaction. On the other hand, in an ex situ measurement, i.e. in a measurement outside the coating chamber, defects and undesirable properties of the coating layer may be determined even if not corrected promptly.

In some embodiments, the measurement mechanism is arranged within the coating chamber for providing an in situ measurement of the characteristic of the coating layer deposited on the substrate. As used herein, an “in situ measurement” is one that takes place substantially in the same place as the coating process, i.e. in the vacuum coating chamber.

An in situ measurement in a vacuum atmosphere requires a measurement device that functions under vacuum conditions. In this way, an online measurement of the thickness of the silicon layer may be implemented, providing a short reaction time when the coating parameters, and thus the physical characteristic, diverge from a desired nominal value range.

In some embodiments, therefore, the measurement mechanism comprises an infrared spectroscopic measurement mechanism. An infrared spectroscopic measurement mechanism is an optical measurement mechanism that allows a contactless, nondestructive measurement of the coating layer. Besides allowing an in situ measurement, the infrared spectroscopic measurement mechanism may show considerable effect when the physical properties of the layer change. For example, in a typical solar application, layers of a thickness of more 200 nm may generate reflection maxima in the infrared spectral range, which may be easily evaluated because of their spectral position. The refraction index may be approximately 3.5 in some embodiments.

In one embodiment, the infrared measurement mechanism comprises an infrared emission source for emitting infrared radiation to be reflected from the substrate and/or from the coating layer deposited on the substrate. The infrared emission source may emit radiation having one or a plurality of discrete wavelengths or a spectral range of infrared radiation.

In particular embodiments, the infrared spectroscopic measurement mechanism may comprise an infrared detector for detecting infrared radiation reflected from the substrate and/or from the coating layer deposited thereon as a function of the wavelength of the infrared radiation.

The spectral distribution (e.g. the intensities) of reflected infrared radiation depends on the physical characteristics of the substrate and/or of the coating layer. Therefore, an alteration of a characteristic, e.g. of the thickness of the coating layer, results in a modified infrared reflection spectrum. The modification of the infrared reflection spectrum allows conclusions to be drawn about the nature of the modification of a particular physical property. For example, a reduction of the thickness results in a first modification of the infrared reflection spectrum, whereas an increase of the thickness of the coating layer results in a second modification of the infrared reflection spectrum. The quantity of the decrease and the increase of the thickness of the coating layer respectively may also be determined from the modifications in the infrared reflection spectrum.

In a particular embodiment, the vacuum coating installation comprises a vacuum strip coating installation.

An in situ measurement according to the invention is particularly suitable for being used in a continuous coating process. In vacuum strip (band/tab) coating installations, a first pulley carries a flexible substrate (e.g. made of metal and/or Al/Mo and/or a substrate such as a plastic substrate coated with a metal/Al/Mo layer) wound up thereon. The first pulley continuously provides a strip of substrate material, and a second pulley (take-up pulley) receives and winds up the coated strip of substrate material. Between the first pulley and the second pulley, coating tools are arranged to deposit a silicon layer on the substrate passing the coating tool, e.g. in an evaporation coating process, a CVD coating process, a PVD coating process, a sputter coating process, a plasma-supported coating process, etc.

The measurement mechanism, e.g. a sensor device, is arranged between a coating section, wherein the silicon layer is deposited on a portion of the substrate strip, and the second pulley, i.e. downstream the coating section. The sensor carries out the measurement for determining the thickness of the silicon layer. The in situ measurement may be carried out online while the coated strip passes the sensor device continuously. This allows for a continuous control, e.g. a feedback control, of the thickness of the silicon layer and the parameters of the coating process, especially of the parameters having an effect on the thickness of the layer.

Embodiments of the invention also provide methods of producing a coating layer on a substrate, and comprise the following: a) providing a continuously moving substrate in a coating chamber; b) depositing a coating layer having a physical characteristic, particularly a thickness, on a first section of the surface of the substrate in the coating chamber while the first section of the surface of the substrate passes the coating section; and c) determining the physical characteristic, particularly the thickness, of the coating layer deposited on the first section of the surface of the substrate downstream the coating section in the coating chamber by using an infrared spectroscopic measuring method. The method may further comprise d) feedback controlling one or more parameters of the coating process responsive to the physical characteristic for controlling the thickness of the coating layer deposited on a second section of the surface of the substrate in the coating section of the coating chamber while the second section of the surface of the substrate passes the coating section. This step d) may include providing feedback control parameters for influencing the physical characteristic of the coating layer deposited on the surface of the substrate in method step b) responsive to the physical characteristic measured in method step c).

The method step c) of determining the physical characteristic may include measuring the physical characteristic within the coating chamber.

The method step b) of depositing a coating layer may comprise using a coating process, e.g. a PVD process, a CVD process, a sputter process, an evaporation process, a plasma-enhanced process, etc. In a continuous coating process, a first section of the substrate is coated while a second section of the substrate that has already been provided with a coating layer is subject to the method according to c).

In one embodiment of the invention, method step c) of measuring the physical characteristic includes an infrared spectroscopic measuring method. This optical measurement may be contactless and thus a nondestructive step.

The infrared spectroscopic measuring method may moreover include measuring an infrared radiation reflection spectrum reflected from the substrate and/or the coating layer deposited on the surface of the substrate. An infrared reflection spectroscopic method is suitable for measuring properties and/or the thickness of a silicon layer deposited on a substrate in a vacuum atmosphere, i.e. in situ. The incoming radiation may have one or more discrete wavelengths or be a continuous wavelength spectrum of a spectral range.

In particular embodiments, the intensity of the infrared radiation reflection spectrum is measured as a function of the wavelength of the radiation. An example may be a measurement of the intensity as a function of the wavelength of the reflected infrared radiation. It may also be possible to vary the wavelength of the incoming radiation during a measurement cycle. A spectroscopic method may be used for determining the infrared reflection spectrum of a silicon layer (e.g. α-Si, n-Si) deposited on a metal substrate or on a substrate, such as a plastic substrate, coated with a metal layer. The spectral wavelength range may be above 1000 nm, up to approximately 1700 nm. An advantage of a measurement of a reflection spectrum of a silicon layer deposited on a metal foil in the infrared wavelength range is that silicon is transparent for electromagnetic radiation above 1000 nm. Therefore, thin layers may be measured as well as relatively thick layers (compared with the wavelength of the radiation). Furthermore, the influence of structures and textures used in solar technology are considerably reduced. There is no scattered light that would considerably disturb the optical measurement.

An expected spectrum corresponding to a particular thickness may be obtained by computation or by measuring a spectrum of a standard. During the measurement of the thickness, the infrared radiation spectrum is compared with these spectra to determine deviations from the standard.

In one embodiment, the method step b) includes depositing a coating layer on a surface of the substrate using a vacuum strip coating process.

In one embodiment, the method step b) includes depositing a silicon layer on the surface of the substrate. The substrate may be a metal substrate and/or a metal substrate coated with an aluminum or molybdenum layer.

Methods of the invention provide for measuring the thickness of a silicon coating layer deposited on a surface of a substrate, comprising determining the thickness of the silicon coating layer deposited on the surface of the substrate and including measuring the thickness using an infrared spectroscopic measurement method within a vacuum coating chamber. The method may be particularly a method according to steps c) and/or d) as described above in connection with the method of producing a coating layer on a substrate.

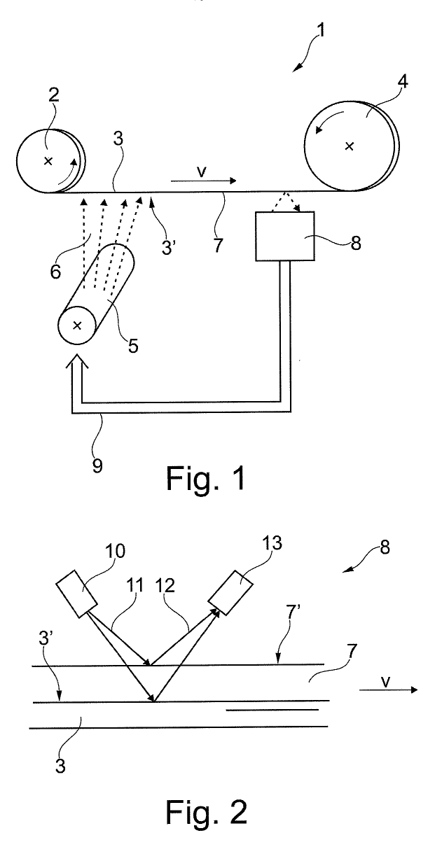

FIG. 1 is a schematic view of a strip coating system 1 according to an embodiment of the invention.

The strip coating system 1 comprises a first pulley 2 carrying an elongated flexible metal or Al/Mo coated metal substrate 3 wound up on the first pulley 2. Furthermore, the strip coating system 1 has a second pulley 4 (take-up pulley) for taking up the coated substrate 3.

The coating process carried out in the strip coating system 1 may be a continuous coating process. During the coating process, the first pulley 2 and the second pulley 4 are rotated to move the substrate 3 continuously past a coating tool 5 to deposit the coating particles 6 on a surface 3′ of the substrate 3.

After having passed the coating section with a speed v, the substrate carrying a coating layer 7 on the surface 3′ thereof passes an infrared spectroscopic measurement device 8 for measuring an infrared reflection spectrum of the coating layer 7 for determining the thickness of the coating layer 7.

The coating tool 5 may be any suitable coating tool for depositing a silicon (or any layer having similar properties with respect to the possibility of an infrared spectroscopic measurement) on a substrate, e.g. a sputter coating tool, a CVD coating tool, a PVD coating tool, an evaporation tool, a tool for plasma-enhanced processes, etc.

An arrow 9 in FIG. 1 indicates a feedback control between the infrared measurement device 8 and the coating tool 5. The feedback control 9 controls one or more process parameters of the coating tool 5 responsive to the measurement of the thickness of the coating layer 7 detected by the measurement tool 8. Thus, an in situ online measurement of the thickness of the coating layer 7 may be implemented.

The described components 2, 4, 5, and 8, as well as the substrate 3, the coating particles 6 forming the silicon layer 7 on the substrate 3, are arranged and accommodated within a vacuum coating chamber (not illustrated), particularly within the vacuum coating chamber of a vacuum strip coating installation (not illustrated).

FIG. 2 illustrates a particular embodiment of the infrared measurement arrangement 8 of FIG. 1.

The infrared measurement device 8 comprises an infrared radiation emitter 10 to emit a single wavelength or a spectral range of infrared radiation 11. The bundle 11 of infrared radiation may have one or more discrete wavelengths or may be a bundle of a spectral wavelength range.

The emitted radiation 11 is reflected on boundary layers, e.g. on the surface 7′ of the silicon coating layer 7 and/or on the front surface 3′ of the substrate 3. The reflected beam 12 is detected by an infrared detector 13. The infrared measurement device 13 may measure an infrared reflection intensity spectrum, e.g. as a function of one or more wavelengths of the reflected infrared radiation, as a function of an angle of incidence of the incoming beam, etc.

During a measurement, the infrared detector 13 may be arranged in a particular angle relative to the surface 3′ of the substrate 3. The angle may be varied during a measurement or between two measurements. The reflected infrared radiation 12 is detected at a particular wavelength and/or as an intensity spectrum of a number of different wavelengths.

These methods of determining the thickness of a silicon layer 7 may be particularly suitable for measuring online in a vacuum atmosphere delivering good results even if the surface 7′ of the silicon layer 7 is structured or patterned.

Having fully described several embodiments of the present invention, many other equivalent or alternative processing systems and methods of the present invention will be apparent to those of skill in the art. These alternatives and equivalents are intended to be included within the scope of the invention, as defined by the following claims.

What is claimed is:

1. A vacuum coating installation for coating a substrate in a continuous coating process, the vacuum coating installation comprising:
a coating chamber;
coating tools for depositing a coating layer on the substrate in a coating section of the coating chamber; and
a determining mechanism for determining a physical characteristic of the coating layer deposited on the substrate,
wherein:
the determining mechanism comprises an infrared spectroscopic measurement mechanism arranged downstream the coating section for measuring the physical characteristic of the coating layer deposited on the substrate;
the vacuum coating installation includes a feedback control unit for controlling one or more parameters of the vacuum coating installation responsive to the physical characteristic determined by the determining mechanism for controlling a thickness of the coating layer deposited in the coating section.

2. The vacuum coating installation according to claim 1 wherein the physical characteristic comprises the thickness of the coating layer.

3. The vacuum coating installation according to claim 1 wherein the measurement mechanism is arranged within the coating chamber for providing an in situ measurement of the characteristic of the coating layer deposited on the substrate.

4. The vacuum coating installation according to claim 3 wherein the infrared spectroscopic measurement mechanism comprises an infrared emission source for emitting infrared radiation to be reflected from the substrate and/or the coating layer deposited on the substrate.

5. The vacuum coating installation according to claim 4 wherein the infrared spectroscopic measurement mechanism comprises an infrared detector for detecting infrared radiation reflected from the substrate and/or the coating layer deposited on the substrate as a function of a wavelength of the infrared radiation.

6. The vacuum coating installation according to claim 1 wherein the vacuum coating installation comprises a vacuum strip coating installation.

7. The vacuum coating installation according to claim 1 further comprising a control unit for controlling one or more parameters of the vacuum coating installation responsive to the physical characteristic determined by the determining mechanism.

8. A coating method of producing a coating layer on a substrate, the coating method comprising:
a) providing a continuously moving substrate in a coating chamber;
b) depositing a coating layer having a physical characteristic on a first section of a surface of the substrate in a coating section of the coating chamber while the first section of the surface of the substrate passes the coating section;
c) determining the physical characteristic of the coating layer deposited on the first section of the surface of the substrate downstream the coating section in the coating chamber by using an infrared spectroscopic measuring method; and
d) feedback controlling one or more parameters of the coating process responsive to the physical characteristic for controlling the thickness of the coating layer deposited on a second section of the surface of the substrate in the coating section of the coating chamber while the second section of the surface of the substrate passes the coating section.

9. The method according to claim 8 wherein the physical characteristic comprises the thickness of the coating layer.

10. The method according to claim 8 wherein the infrared spectroscopic measuring method includes measuring an infrared radiation reflection spectrum reflected from the substrate and/or the coating layer deposited on the surface of the substrate.

11. The method according to claim 10 wherein the intensity of the infrared radiation reflection spectrum is measured as a function of a wavelength of the radiation.

12. The method according to claim 8 wherein step b) includes depositing the coating layer on the surface of the substrate using a vacuum strip coating process.

13. The method according to claim 8 wherein step b) includes depositing a silicon layer on the surface of the substrate.
